(19) United States
(12) Patent Application Publication
(10) Pub. No.: US 2009/0305506 A1
(43) Pub. Date: Dec. 10, 2009

(54) SELF-ALIGNED DUAL PATTERNING INTEGRATION SCHEME

(76) Inventor: JOERG LINZ, Dresden (DE)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/135,408

(22) Filed: Jun. 9, 2008

(51) Int. Cl. H01L 21/311

(52) U.S. Cl. 438/696; 257/E21.257

(57) ABSTRACT

A method of self-aligned dual patterning is described. The method includes first providing a substrate having a stack of films thereon. A template mask is then formed above the stack of films. A liner layer is formed above the stack of films and conformal with the template mask. A spacer-forming material layer is formed over and conformal with the liner layer. The spacer-forming material layer is then etched to form a spacer mask and to exose a portion of the liner layer. The exposed portion of the liner layer and the template mask are then removed. Finally, an image of the spacer mask is transferred to the stack of films.

### BACKGROUND

1) Field

Embodiments of the present invention pertain to the field of Semiconductor Processing and, in particular, to integration schemes for patterning films.

2) Description of Related Art

For the past several decades, the scaling of features in integrated circuits has been the driving force behind an ever-growing semiconductor industry. Scaling to smaller and smaller features enables increased densities of functional units on the limited real estate of semiconductor chips. For example, shrinking transistor size allows for the incorporation of an increased number of logic and memory devices on a microprocessor, lending to the fabrication of products with increased complexity.

Scaling has not been without consequence, however. As the dimensions of the fundamental building blocks of microelectronic circuitry are reduced and as the sheer number of fundamental building blocks fabricated in a given region is increased, the constraints on the lithographic processes used to pattern these building blocks have become overwhelming. In particular, there may be a trade-off between the smallest dimension of a feature patterned in a semiconductor stack (the critical dimension) and the spacing between such features. FIGS. 1A-1C illustrate cross-sectional views representing a conventional semiconductor lithographic process, in accordance with the prior art.

Referring to FIG. 1A, a photo-resist layer 104 is provided above a semiconductor stack 102. A mask or reticle 106 is positioned above photo-resist layer 104. A lithographic process includes exposure of photo-resist layer 104 to light (hv) having a particular wavelength, as indicated by the arrows in FIG. 1A. Referring to FIG. 1B, photo-resist layer 104 is subsequently developed to provide patterned photo-resist layer 108 above semiconductor stack 102. The portions of photo-resist layer 104 that were exposed to light are now removed. The width of each feature of patterned photo-resist layer 108 is depicted by the width ‘x.’ The spacing between each feature is depicted by the spacing ‘y.’ Typically, the limit for a particular lithographic process is to provide features having a critical dimension equal to the spacing between the features, e.g., x=y, as depicted in FIG. 1B.

Referring to FIG. 1C, the critical dimension (e.g., the width ‘x’) of a feature may be reduced to form patterned photo-resist layer 110 above semiconductor stack 102. The critical dimension may be shrunk or reduced by over-exposing photo-resist layer 104 during the lithographic step depicted in FIG. 1A or by subsequently trimming patterned photo-resist layer 108 from FIG. 1B. However, a reduction in critical dimension comes at the expense of an increased spacing between features, as depicted by spacing ‘y’ in FIG. 1C. There may be a trade-off between the smallest achievable dimension of each of the features from patterned photo-resist layer 110 and the spacing between each feature.

### SUMMARY

Embodiments of the present invention include a method of self-aligned dual patterning. In an embodiment, a substrate is provided having a stack of films thereon. A template mask is then formed above the stack of films. A liner layer is formed above the stack of films and conformal with the template mask. A spacer-forming material layer is formed over and conformal with the liner layer. The spacer-forming material layer is then etched to form a spacer mask and to expose a portion of the liner layer. The exposed portion of the liner layer and the template mask are then removed. An image of the spacer mask is then transferred to the stack of films.

In another embodiment, a method of self-aligned dual patterning includes first providing a substrate having a stack of films thereon. A first film of the stack of films is farthest from the substrate. A template mask is then formed above the first film of the stack of films. A liner layer is formed above the first film of the stack of films and conformal with the template mask. A spacer-forming material layer is formed over and conformal with the liner layer. The spacer-forming material layer and the first film of the stack of films have a similar etch characteristic. The spacer-forming material layer is then etched to form a spacer mask and to expose a portion of the liner layer. The exposed portion of the liner layer and the template mask are then removed. An image of the spacer mask is then transferred to the stack of films.

In yet another embodiment, a substrate is provided having a stack of films thereon. A template mask is then formed above the stack of films. A line of the template mask has a first width. A liner layer is formed above the stack of films and conformal with the template mask. A spacer-forming material layer is formed over and conformal with the liner layer. The spacer-forming material layer is then etched to form a spacer mask and to expose a portion of the liner layer. A spacer of the spacer mask has a second width approximately equal to the sum of the first width of the template mask and two times the thickness of the liner layer. The exposed portion of the liner layer and the template mask are then removed. An image of the spacer mask is then transferred to the stack of films.

### BRIEF DESCRIPTION OF THE DRAWINGS

FIG. 1A illustrates a cross-sectional view representing an operation in a conventional semiconductor lithographic process, wherein a photo-resist layer is provided above a semiconductor stack, in accordance with the prior art.

FIG. 1B illustrates a cross-sectional view representing an operation in a conventional semiconductor lithographic process, wherein a photo-resist layer is patterned above a semiconductor stack, and wherein features of the photo-resist layer have a critical dimension equal to the spacing between the features, in accordance with the prior art.

FIG. 1C illustrates a cross-sectional view representing an operation in a conventional semiconductor lithographic process, wherein the critical dimension of a patterned photo-resist layer is reduced, in accordance with the prior art.

FIGS. 2A-2C illustrate cross-sectional views representing a series of operations in a self-aligned dual patterning integration scheme, wherein a liner layer is not used in the integration scheme, in accordance with an embodiment of the present invention.

FIGS. 3A-3H illustrate cross-sectional views representing a series of operations in a self-aligned dual patterning integration scheme, wherein a liner layer is used in the integration scheme, in accordance with an embodiment of the present invention.

FIG. 4 is a Flowchart representing a series of operations in a self-aligned dual patterning integration scheme, in accordance with an embodiment of the present invention.

FIG. 5 illustrates a cross-sectional view representing an operation in a spacer mask cropping process, in accordance with an embodiment of the present invention.

FIG. 6 illustrates a cross-sectional view representing an operation in an area-preservation process, in accordance with an embodiment of the present invention.

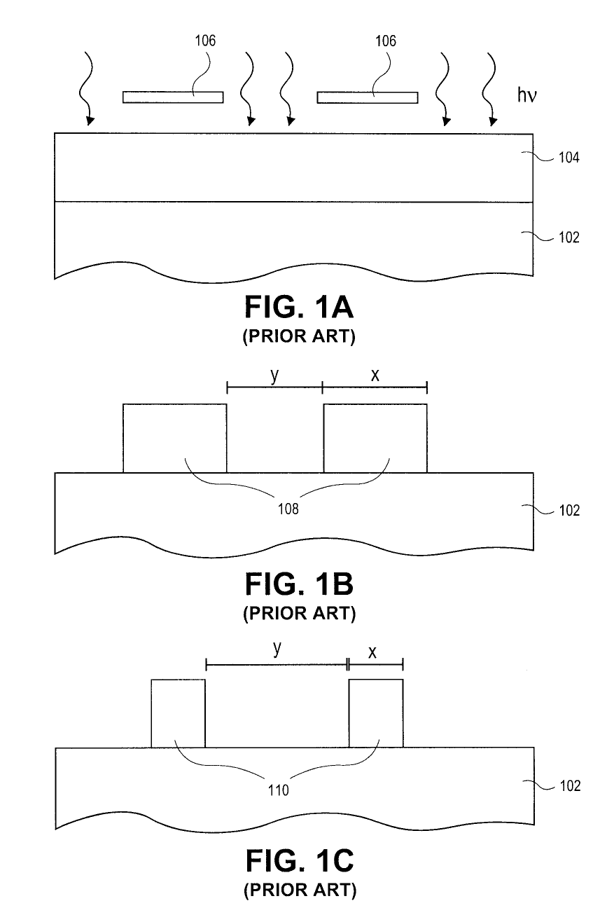

### DETAILED DESCRIPTION

A method of self-aligned dual patterning is described. In the following description, numerous specific details are set forth, such as fabrication conditions and material regimes, in order to provide a thorough understanding of the present invention. It will be apparent to one skilled in the art that the present invention may be practiced without these specific details. In other instances, well-known features, such as integrated circuit design layouts or photo-resist development processes, are not described in detail in order to not unnecessarily obscure the present invention. Furthermore, it is to be understood that the various embodiments shown in the Figures are illustrative representations and are not necessarily drawn to scale.

Disclosed herein is a method of self-aligned dual patterning. The method may include first providing a substrate having a stack of films thereon. In one embodiment, a template mask is then formed above the stack of films. A liner layer is formed above the stack of films and conformal with the template mask. A spacer-forming material layer is formed over and conformal with the liner layer. The spacer-forming material layer may then be etched to form a spacer mask and to expose a portion of the liner layer. In one embodiment, the exposed portion of the liner layer and the template mask are then removed. Finally, an image of the spacer mask may then be transferred to the stack of films.

The use of a liner layer in a self-aligned dual patterning integration scheme may minimize undesirable variations in such an integration scheme. For example, in accordance with an embodiment of the present invention, a liner layer is used during the fabrication of a spacer mask. The liner layer protects, from etching during formation of the spacer mask, exposed regions of a hard-mask layer that is disposed underneath the spacer mask and to which the image of the spacer mask will ultimately be transferred. In one embodiment, use of the liner layer during formation of a spacer mask enables the transfer of an image of the spacer mask to a hard-mask layer having uniform thickness throughout all regions of the layer.

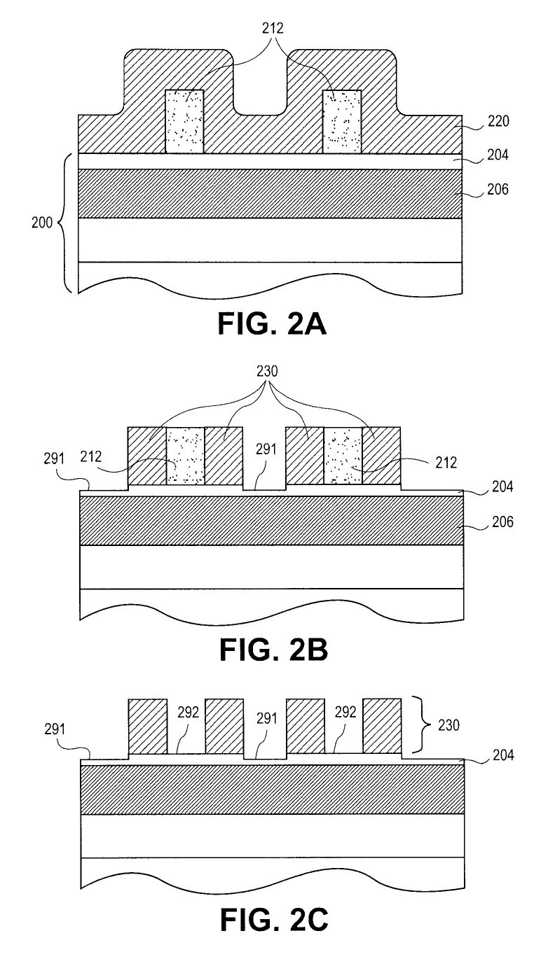

In an aspect of the invention, a spacer-forming material layer may be etched above a hard-mask layer to form a spacer mask for use in a self-aligned dual patterning integration scheme. FIGS. 2A-2C illustrate cross-sectional views representing a series of operations in a self-aligned dual patterning integration scheme, wherein a liner layer is not used in the integration scheme, in accordance with an embodiment of the present invention.

Referring to FIG. 2A, a spacer-forming material layer 220 is disposed above a template mask 212 which resides above a stack of films 200. In one embodiment, stack of films 200 includes a first hard-mask layer 204 and a second hard-mask layer 206.

Referring to FIG. 2B, spacer-forming material layer 220 is etched to form a spacer mask 230. For example, in accordance with an embodiment of the present invention, spacer mask 230 is fabricated having spacer lines formed adjacent to the sidewalls of template mask 212. That is, for every line in template mask 212, two spacer lines of spacer mask 230 are generated. A spacer mask providing substantially the same critical dimension (e.g., the same feature width) for each line, but having double the density of lines in a particular region, may thus be fabricated. For example, in one embodiment, the pitch of template mask 212 is selected to be 4 in order to ultimately provide spacer mask 230 having a pitch of 2. However, in accordance with an embodiment of the present invention, in order to ensure discontinuity of spacer lines across a wafer, spacer-forming material layer 220 is over-etched to form spacer mask 230. Such an over-etch may undesirably remove portions 291 of the exposed regions of first hard-mask 204, as depicted in FIG. 2B.

Referring to FIG. 2C, template mask 212 is removed to leave only spacer mask 230 above first hard-mask layer 204. In accordance with an embodiment of the present invention, exposed portions 292 of first hard-mask layer 204, that were covered by template mask 212 during the formation of spacer mask 230, are thicker than portions 291 which were partially etched during the formation of spacer mask 230. The difference in thicknesses of portions 291 and 292 of first hard-mask layer 204 may lead to unacceptable degrees of variation when transferring the image of spacer mask 230 to first hard-mask layer 204 and, ultimately, to second hard-mask layer 204. Variations may occur because the time required to subsequently etch the different portions 291 and 292 of first hard-mask layer 204 differ as a result of their differing thickness. Thus, portions 291 may be exposed to an over-etch during completion of the etch of portions 292, leading to undesirable undercut in certain areas of first hard-mask layer 204.

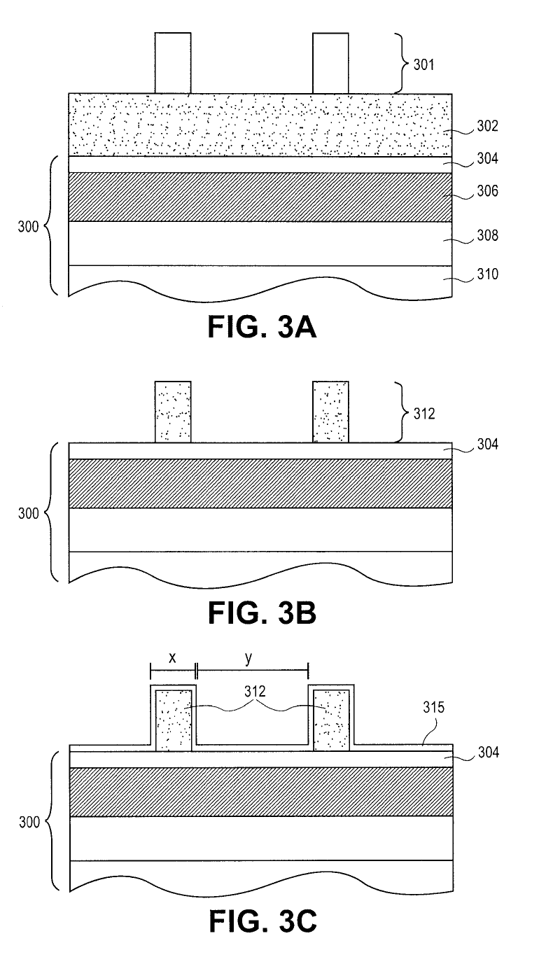

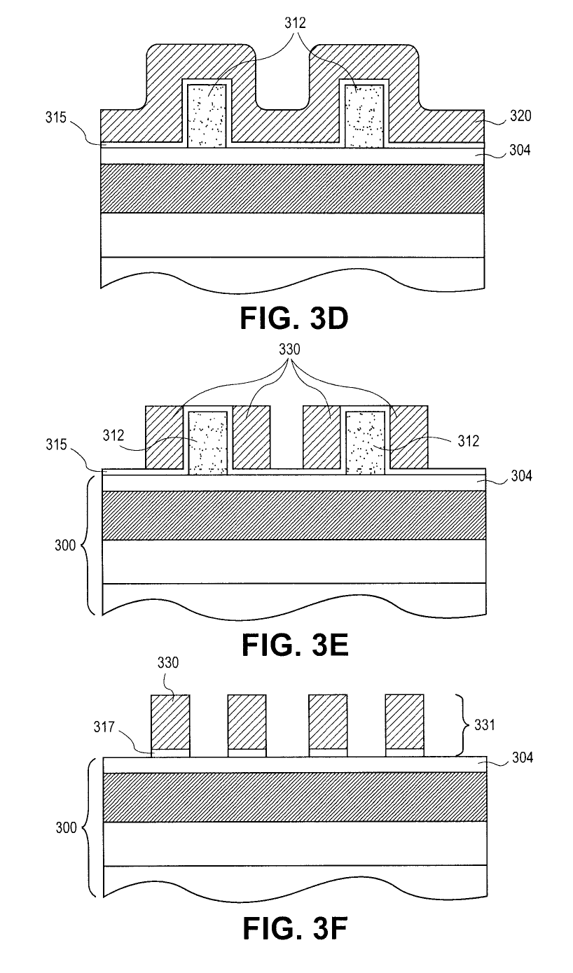

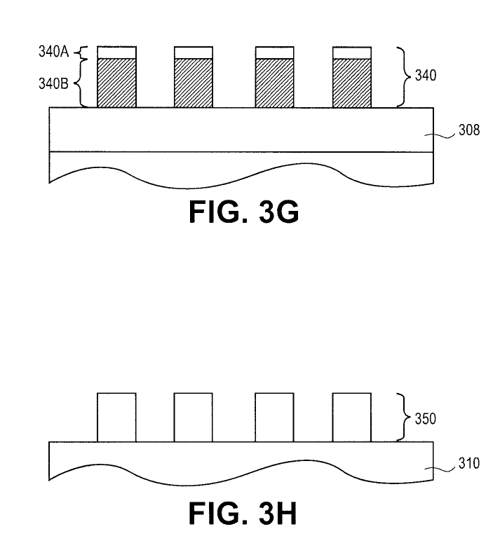

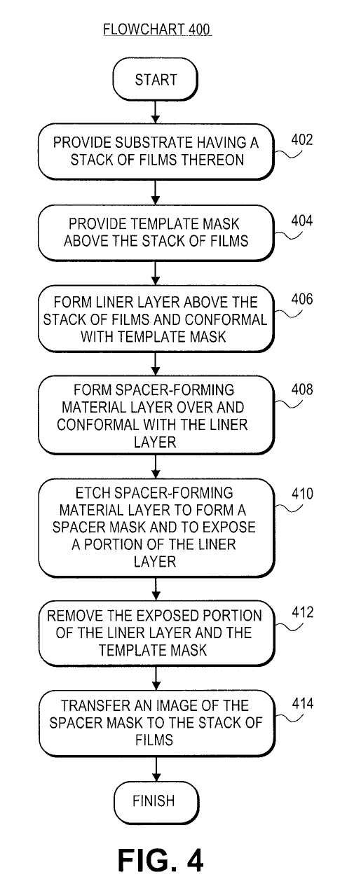

Accordingly, in an aspect of the invention, a spacer-forming material layer may be formed above a liner layer, which protects a hard-mask layer, to form a spacer mask for use in a self-aligned dual patterning integration scheme. FIGS. 3A-3H illustrate cross-sectional views representing a series of operations in a self-aligned dual patterning integration scheme, wherein a liner layer is used in the integration scheme, in accordance with an embodiment of the present invention. FIG. 4 is a Flowchart 400 representing a series of operations in a self-aligned dual patterning integration scheme, in accordance with an embodiment of the present invention.

Referring to FIG. 3A and corresponding operation 402 of Flowchart 400, a substrate is provided having a stack of films thereon. For example, in an embodiment of the present invention, a template mask precursor layer 302 is disposed above a stack 300 which includes a substrate 310 and films 304, 306 and 308 thereon. In accordance with an embodiment of the present invention, at least a portion of stack 300 will ultimately be patterned by using a self-aligned dual patterning integration scheme. For example, in one embodiment, a device layer having a hard-mask stack thereon is patterned by first forming a spacer mask. Thus, in a specific embodiment, structure 300 includes a first hard-mask layer 304, a second hard-mask layer 306 and a device layer 308, as depicted in FIG. 3A. In a particular embodiment, first hard-mask layer 304 and second hard-mask layer 306 are removed following a patterning process, while device layer 308 is patterned and ultimately retained. In other embodiments, a hard-mask stack disposed above a device layer includes additional layers which are used in various regional etch stop schemes.

Template mask precursor layer 302 may be composed of a material suitable for patterning by a lithographic and etch process and suitable for withstanding a spacer mask formation process carried out thereon. In accordance with an embodiment of the present invention, template mask precursor layer 302 is composed of amorphous silicon. However, other insulator or semiconductor materials may be used. For example, in another embodiment, template mask precursor layer 302 is composed of a material such as, but not limited to, silicon nitride, silicon oxide, germanium, silicon-germanium or poly-crystalline silicon. In an alternative embodiment, a photo-resist layer is patterned directly to form a photo-resist template mask, eliminating the need for template mask precursor layer 302.

First hard-mask layer 304 may be composed of any material suitable for transferring an image of a spacer mask therein. The material of first hard-mask layer 304 may also be suitable to withstand an etch process used to form a spacer mask, e.g., suitable to protect second hard-mask layer 306 during formation of a spacer mask. In accordance with an embodiment of the present invention, a liner layer is used to protect first hard-mask layer 304 during an etch process used to form the spacer mask, as described below. In one embodiment, first hard-mask layer 304 is composed of a material such as, but not limited to, silicon oxide or silicon nitride. The thickness of first hard-mask layer 304 may be sufficiently thick to inhibit the formation of pinholes that may undesirably expose second hard-mask layer 306 to an etch process used to form a spacer mask or used to remove a template mask. In one embodiment, the thickness of first hard-mask layer 304 is in the range of 15-40 nanometers.

Second hard-mask layer 306 may be composed of any material suitable to form a patterning mask based on the transferred image of a spacer mask. For example, in a accordance with an embodiment of the present invention, second hard-mask layer 306 is composed substantially of carbon atoms. In one embodiment, second hard-mask layer 306 consists essentially of a mixture of sp³ (diamond-like)-, sp² (graphitic)- and sp¹(pyrolitic)-hybridized carbon atoms formed from a chemical vapor deposition process using hydrocarbon precursor molecules. Such a film is known in the art as an amorphous carbon film, an example of which is the Advanced Patterning Film™ (APF™) from Applied Materials. The thickness of second hard-mask layer 306 may be any thickness suitable to provide a practical aspect ratio for use in a subsequently formed patterning mask. In a particular embodiment, the thickness of second hard-mask layer 306 is in the range of 3.125-6.875 times the targeted width of each of the lines of a subsequently formed patterning mask.

Device layer 308 may be any layer desirable for device fabrication or any other structure fabrication requiring a self-aligned dual patterning integration scheme (e.g. semiconductor device structures, MEMS structures and metal line structures). For example, in accordance with an embodiment of the present invention, device layer 308 is composed of a material that can be suitably patterned into an array of distinctly defined semiconductor structures. In one embodiment, device layer 308 is composed of a group IV-based material or a III-V material. Additionally, device layer 308 may comprise a morphology and a thickness suitable for patterning into an array of distinctly defined semiconductor structures. In an embodiment, the morphology of device layer 308 is a morphology such as, but not limited to, amorphous, mono-crystalline or poly-crystalline. In one embodiment, device layer 308 includes charge-carrier dopant impurity atoms. In a specific embodiment, device layer 308 has a thickness in the range of 50-1000 nanometers. Device layer 308 may be composed of a metal. In one embodiment, device layer 308 is composed of a metal species such as, but not limited to, a metal nitride, a metal carbide, a metal silicide, hafnium, zirconium, titanium, tantalum, aluminum, ruthenium, palladium, platinum, cobalt, copper or nickel.

Substrate 310 may be composed of a material suitable to withstand a manufacturing process and upon which material films may suitably be disposed. In an embodiment, substrate 310 is composed of group IV-based materials such as, but not limited to, crystalline silicon, germanium or silicon/germanium. In another embodiment, substrate 310 is composed of a III-V material. Substrate 310 may also include an insulating layer. In one embodiment, the insulating layer is composed of a material such as, but not limited to, silicon nitride, silicon oxy-nitride or a high-k dielectric layer. In an alternative embodiment, substrate 310 is composed of a flexible plastic sheet.

Referring again to FIG. 3A, a photo-resist mask 301 is disposed above template mask precursor layer 302. Photo-resist mask 301 may be composed of a material suitable for use in a lithographic process. That is, in one embodiment, photo-resist mask 301 is formed upon exposure of a blanket film of photo-resist to a light source and subsequent development of the exposed photo-resist. In an embodiment, photo-resist mask 301 is composed of a positive photo-resist material. In a specific embodiment, photo-resist mask 301 is composed of a positive photo-resist material such as, but not limited to, a 248 nm resist, a 193 nm resist, a 157 nm resist, an extreme ultra-violet (EUV) resist or a phenolic resin matrix with a diazonaphthoquinone sensitizer. In another embodiment, photo-resist mask 301 is composed of a negative photo-resist material. In a specific embodiment, photo-resist mask 301 is composed of a negative photo-resist material such as, but not limited to, poly-cis-isoprene or poly-vinyl-cinnamate.

Referring to FIG. 3B and corresponding operation 404 of Flowchart 400, a template mask is provided above a stack of films. In accordance with an embodiment of the present invention, a template mask 312 is formed by transferring the image of photo-resist mask 301 into template mask precursor layer 302 above stack 300 and, specifically, directly above first hard-mask layer 304. The image of photo-resist mask 301 may be transferred into template mask precursor layer 302 by a process suitable to maintain the dimensions of the features of photo-resist mask 301. Furthermore, in an embodiment, the image of photo-resist mask 301 is transferred into template mask precursor layer 302 by a process suitable to provide approximately vertical sidewalls for the features of template mask 312, as depicted in FIG. 3B. In one embodiment, template mask precursor layer 302 is composed of amorphous silicon and the image of photo-resist mask 301 is transferred into template mask precursor layer 302 by a dry etch process using CHF₃ gas. In accordance with an embodiment of the present invention, first hard-mask layer 304 protects second hard-mask layer 306 during the formation of template mask 312.

Referring to FIG. 3C and corresponding operation 406 of Flowchart 400, a liner layer is formed above a stack of films and conformal with a template mask. In accordance with an embodiment of the present invention, a liner layer 315 is deposited directly above first hard-mask layer 304 and conformal with template mask 312. Liner layer 315 may be composed of a material suitable to substantially prevent the etching of exposed portions of first-hard mask layer 304 during the formation of a spacer mask above first-hard mask layer 304. Also, in an embodiment, liner layer 315 is composed of a material having an etch characteristic similar to an etch characteristic of template mask 312. In that embodiment, a portion of liner layer 315 can be removed in the same process step as the removal of template mask 312, as described below. In one embodiment, liner layer 315 and template mask 312 are composed of substantially the same material. In a specific embodiment, both liner layer 315 and template mask 312 are composed of amorphous silicon. Liner layer 315 may be deposited by a process suitable to provide a conformal layer on the sidewalls of template mask 312, as depicted in FIG. 3C. In one embodiment, liner layer 315 is deposited by a chemical vapor deposition (CVD) technique such as, but not limited to, molecular-organic CVD, low-pressure CVD or plasma-enhanced CVD.

The total height of the combined heights of liner layer 315 and template mask 312 may be sufficiently short to prevent spacer mask line-collapse of a subsequently formed spacer mask formed thereon and sufficiently tall to enable critical dimension control of the spacer mask lines. In one embodiment, the total height of the combined heights of liner layer 315 and template mask 312 is approximately in the range of 4.06-5.625 times the targeted line width of a subsequently formed spacer mask. In an embodiment, the contribution of the height of liner layer 315 (e.g., the thickness of liner layer 315) is approximately in the range of 3-5% of the total height of the combined heights of liner layer 315 and template mask 312. In a specific embodiment, liner layer 315 has a thickness approximately in the range of 5-10 nanometers.

The total width of the combined widths of liner layer 315 (taken twice) and template mask 312 may be a dimension suitable for use in a spacer mask fabrication process. In accordance with an embodiment of the present invention, the total width ‘x’ of each feature of template mask 312 and two sidewalls of liner layer 315 is selected to substantially correlate with the desired critical dimension of a subsequently formed semiconductor device feature. For example, in one embodiment, the width ‘x’ is selected to correlate with the desired critical dimension of a gate electrode. In one embodiment, the width ‘x’ is approximately in the range of 10-100 nanometers. The spacing ‘y’ may be selected to optimize a self-aligned dual patterning integration scheme. That is, in accordance with an embodiment of the present invention, a subsequently fabricated spacer mask is targeted such that the width of the spacer lines of the spacer mask are approximately equal to the width ‘x’. Furthermore, the spacing between subsequently formed spacer lines is targeted to be approximately equal to the width ‘x’. Thus, in one embodiment, because the frequency of lines in template mask 312 will ultimately be doubled, the spacing ‘y’ is approximately equal to 3 times the value ‘x,’ as depicted in FIG. 3C. In an embodiment, the contribution of the width of liner layer 315 (e.g., two times thickness of liner layer 315) to the total width of the combined widths of liner layer 315 (taken twice) and a line of template mask 312 is approximately in the range of 20-30% of the total width. In a particular embodiment, liner layer 315 has a thickness of approximately 5 nanometers and a line of template mask 312 has a width of approximately 25 nanometers.

Referring to FIG. 3D and corresponding operation 408 of Flowchart 400, a spacer-forming material layer is formed over and conformal with a liner layer. In accordance with an embodiment of the present invention, a spacer-forming material layer 320 is formed with a uniform thickness over and conformal with liner layer 315. Spacer-forming material layer 320 may be composed of a material suitable to form a reliable mask for use in a subsequent etch process. In accordance with an embodiment of the present invention, spacer-forming material layer 320 is composed of a material such as, but not limited to, silicon nitride, silicon oxide, amorphous silicon or poly-crystalline silicon. In one embodiment, spacer-forming material layer 320 is composed of silicon oxide or silicon nitride, while template mask 312 and liner layer 315 are composed of amorphous silicon. Spacer-forming material layer 320 may be deposited by a process suitable to provide a conformal layer adjacent the portion of liner layer 315 that is along the sidewalls of template mask 312, as depicted in FIG. 3D. In one embodiment, spacer-forming material layer 320 is deposited by a chemical vapor deposition (CVD) technique such as, but not limited to, molecular-organic CVD, low-pressure CVD or plasma-enhanced CVD. Spacer-forming material layer 320 is the source of material for what will ultimately become a spacer mask for use in a self-aligned dual patterning integration scheme.

The thickness of spacer-forming material layer 320 may be selected to determine the width of the features in a subsequently formed spacer mask. Thus, in accordance with an embodiment of the present invention, the thickness of spacer-forming material layer 320 is approximately equal to the total width of the combined widths of liner layer 315 (taken twice) and template mask 312, e.g., approximately equal to width ‘x’, as depicted in FIG. 3D. Although for a self-aligned dual patterning integration scheme the ideal thickness of spacer-forming material layer 320 is the same as the width ‘x’, the initial targeted thickness of spacer-forming material layer 320 may need to be slightly thicker to compensate for the etch process used to pattern thickness of spacer-forming material layer 320. In one embodiment, the thickness of thickness of spacer-forming material layer 320 is approximately 1.06 times the desired feature width of a subsequently formed spacer mask.

Referring to FIG. 3E and corresponding operation 410 of Flowchart 400, a spacer-forming material layer is etched to form a spacer mask. In accordance with an embodiment of the present invention, spacer-forming material layer 320 is etched to form a spacer mask 330 and to expose a portion of liner layer 315. In one embodiment, the lines of spacer mask 330 are conformal with the portions of liner layer 315 along the sidewalls of the features of template mask 312. Thus, there are two lines for spacer mask 330 for every line of template mask 312, as depicted in FIG. 3E.

Spacer-forming material layer 320 may be etched to provide spacer mask 330 by a process suitable to provide well-controlled dimensions. For example, in one embodiment, spacer-forming material layer 320 is etched to form spacer mask 330 by a process that provides a spacer width approximately equal to the width ‘x’, described above. In a particular embodiment, liner layer 315 and template mask 312 are composed of amorphous silicon, spacer-forming material layer 320 is composed of silicon oxide, and spacer-forming material layer 320 is etched to form spacer mask 330 using a dry etch process with a gas such as, but not limited to, C₄F₈, CH₂F₂ or CHF₃. In accordance with an embodiment of the present invention, spacer-forming material layer 320 is etched at least until the portions of liner layer 315 covering the features of template mask 312 are exposed, as depicted in FIG. 3E. In a specific embodiment, spacer-forming material layer 320 is etched until the top surface of the features of template mask 312 are exposed, but this is not depicted in FIG. 3E.

In accordance with an embodiment of the present invention, a portion of structure 300 and, in particular, first hard-mask layer 304 is protected by liner layer 315 during the etching of spacer-forming material layer 320. By protecting first hard-mask layer 304 with liner layer 315 during the etching of spacer-forming material layer 320, spacer-forming material layer 320 may be over-etched in order to ensure complete etching over a range of features without etching portions of first hard-mask layer 304. For example, in one embodiment spacer-forming material layer 320 and first hard-mask layer 304 have a similar etch characteristic, but first hard-mask layer 304 is protected by liner layer 315 during the etching, and even the over-etching, of spacer-forming material layer 320 to form spacer mask 330. In a particular embodiment, spacer-forming material layer 320 is composed of silicon oxide and first hard-mask layer 304 is composed of silicon oxy-nitride. In an embodiment, spacer-forming material layer 320 is etched until the lines of spacer mask 330 are substantially the same height as the portion of liner layer 315 covering the features of template mask 312, as depicted in FIG. 3E. In another embodiment, the lines of spacer mask 330 are recessed below the portion of liner layer 315 covering the features of template mask 312 in order to ensure that the continuity of spacer-forming material layer 320 is broken above and between the lines of spacer mask 330. Spacer-forming material layer 320 may be etched such that the spacer lines of spacer mask 330 retain a substantial portion of the original thickness of spacer-forming material layer 320. Thus, in a particular embodiment, the width of the top surface of each line of spacer mask 330 is substantially the same as the width at the interface of spacer mask 330 and liner layer 315, as depicted in FIG. 3E.

Referring to FIG. 3F and corresponding operation 412 of Flowchart 400, a template mask and an exposed portion of a liner layer are removed. In accordance with an embodiment of the present invention, template mask 312 and the exposed portions of liner layer 315 are removed, leaving only a template mask 331 above first hard-mask layer 304. Template mask 331 includes template mask 330 and the portions 317 of liner layer 315 covered by spacer mask 330.

Template mask 312 and the exposed portions of liner layer 315 may be removed by a technique suitable for selective removal without impacting spacer mask 331 or first hard-mask layer 304. In accordance with an embodiment of the present invention, template mask 312 and the exposed portions of liner layer 315 have a similar etch characteristic and are removed in a single etch process operation. For example, in one embodiment, template mask 312 and the exposed portions of liner layer 315 are both composed of amorphous silicon and are removed by a dry etch process using CHF₃ gas. In an alternative embodiment, template mask 312 and the exposed portions of liner layer 315 do not have a similar etch characteristic and are removed in at least two etch process operations. In an embodiment, spacer mask 331 is used directly to pattern a device layer. In another embodiment, spacer mask 331 cannot withstand an etch process used to pattern a device layer and, accordingly, the image of spacer mask 331 is first transferred into a hard-mask stack and then into a device layer, as described below. In one embodiment, the hard-mask stack is a multi-layer hard-mask stack. In a specific embodiment, the portion of structure 300 and, in particular, the portion of the top surface of first hard-mask layer 304 that was previously masked by liner layer 315 is now exposed, as depicted in FIG. 3F. In accordance with an embodiment of the present invention, all portions of first hard-mask layer 304 have approximately the same thickness because liner layer 315 protected first hard-mask layer 304 during the etching of spacer-forming material layer 320.

Referring to FIG. 3G and corresponding operation 414 of Flowchart 400, an image of a spacer mask is transferred to a stack of films. In accordance with an embodiment of the present invention, an image of spacer mask 331 is transferred to second hard-mask layer 306 via first hard-mask layer 304 to form patterning mask 340 in structure 300. In one embodiment, patterning mask 340 includes a first hard-mask portion 340A and a second hard-mask portion 340B, as depicted in FIG. 3G.

The image of spacer mask 331 may be transferred to first and second hard-mask layers 304 and 306 by a process suitable to reliably maintain the pattern and dimensions of spacer mask 331 during the transfer process. In one embodiment, the image of spacer mask 331 is transferred to first and second hard-mask layers 304 and 306 in a single-step etch process. In accordance with another embodiment of the present invention, the image of spacer mask 331 is transferred into first hard-mask layer 304 and second hard-mask layer in two distinct etch steps, respectively. The image of spacer mask 331 is then transferred from first hard-mask portion 340A to second hard-mask layer 306 in a second etch step. Second hard-mask layer 306 and, hence, second hard-mask 340B of patterning mask 340 may be composed of a material suitable for substantially withstanding an etch process used to subsequently pattern device layer 308. In one embodiment, second hard-mask layer 306 is composed of amorphous carbon and is patterned with the image of spacer mask 331 by an etch process that maintains a substantially vertical profile for each of the lines of patterning mask 340, as depicted in FIG. 3G. In a particular embodiment, second hard-mask layer 306 is composed of amorphous carbon and is etched to form second hard-mask portion 340B of patterning mask 340 with a dry etch process using a plasma composed of gases such as, but not limited to, the combination of O₂ and N₂ or the combination of CH₄, N₂ and O₂. Spacer mask 331 may also be removed, as depicted in FIG. 3G. In accordance with an embodiment of the present invention, spacer mask 330 is removed by an etch process similar to the etch process used to etch spacer-forming material layer 320 to provide spacer mask 330, while the portion 317 of liner layer 315 is removed by an etch process similar to the etch process used to remove the exposed portion of liner layer 315 along with template mask 312. The image of patterning mask 340 may then be transferred to device layer 308 to provide patterned device layer 350, as depicted in FIG. 3H. In one embodiment, patterned device layer 350 is disposed above substrate 310.

Thus, a method to fabricate a patterning mask 340 comprised of lines that double the frequency of the lines from a template mask has been described. Patterning mask 340 may then be used to pattern device layer 308 for, e.g. device fabrication for an integrated circuit. In accordance with an embodiment of the present invention, patterning mask 340 has a second hard-mask portion 340B consisting essentially of amorphous carbon. During an etch process used to pattern device layer 308, the amorphous carbon material becomes passivated and is thus able to retain its image and dimensionality throughout the entire etch of device layer 308. Therefore, although spacer mask 331 and patterned first hard-mask layer 304 have the desired dimensions for patterning device layer 308, the material of spacer mask 331 and first hard-mask layer 304 may not be suitable to withstand a precise image transfer to device layer 308, e.g., these layers may degrade during the etch process. Hence, in accordance with an embodiment of the present invention, the image of spacer mask 331 is first transferred to a layer consisting essentially of amorphous carbon prior to transferring the image to device layer 308, as described in association with FIGS. 3F and 3G.

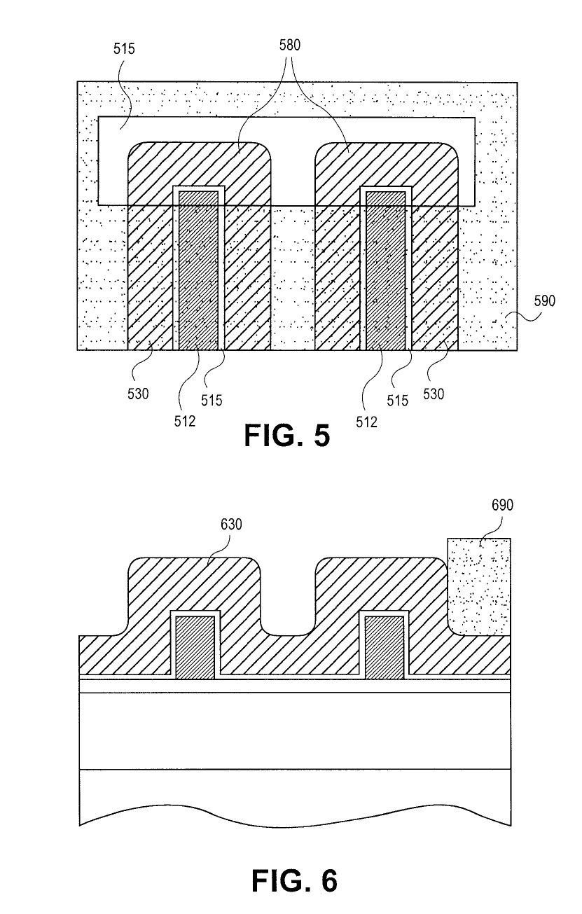

Prior to transferring the image of spacer mask 330 to first and second hard-mask layers 304 and 306, it may be desirable to first crop spacer mask 330 to form a cropped spacer mask. For example, in the etch step used to form spacer mask 330 described in association with FIG. 3E, spacer lines from spacer mask 330 were made discontinuous between neighboring lines of template mask 312 and liner layer 315. However, spacer lines of spacer mask 330 associated with the same line from template mask 312 remain continuous around the ends of each of the lines of template mask 312. In accordance with another embodiment of the present invention, the continuity between pairs of spacer lines in spacer mask 330 is broken around the ends of the lines of template mask 312 to enable more flexibility in design lay-outs for subsequent semiconductor device manufacture. For example, FIG. 5 illustrates a cross-sectional view representing an operation in a spacer mask cropping process, in accordance with an embodiment of the present invention. In an embodiment, a layer of photo-resist 590 is deposited and patterned above a spacer mask 530, a template mask 512 and a liner layer 515. For clarity, the portion of liner layer 515 above template mask 512 (if not removed during the formation of spacer mask 330) is not depicted. In one embodiment, the ends of spacer lines 580 of spacer mask 530 are etched to form a cropped spacer mask prior to the removal of template mask 512 and the portions of liner layer 515 not covered by the cropped spacer mask. In an alternative embodiment, the ends of spacer lines 580 of spacer mask 530 are etched to form a cropped spacer mask subsequent to the removal of template mask 512.

When forming spacer mask 331, it may be desirable to retain more than just the portion of spacer-forming material layer 320 that is conformal with the portions of liner layer 315 adjacent the sidewalls of template mask 312. Thus, in accordance with another embodiment of the present invention, area-preservation regions are retained during the formation of spacer mask 330. FIG. 6 illustrates a cross-sectional view representing an operation in an area-preservation process, in accordance with an embodiment of the present invention. In an embodiment, a layer of photo-resist 690 is disposed above a spacer-forming material layer 630 prior to etching. A portion of spacer-forming material layer 630 that would otherwise be removed in the etch step used to form a spacer mask is retained in such an area-preservation process. Thus, a spacer mask may include an area-preservation portion.

Thus, a method of self-aligned dual patterning has been disclosed. In accordance with an embodiment of the present invention, a substrate having a stack of films thereon is first provided. A template mask is then formed above the stack of films. A liner layer is formed above the stack of films and conformal with the template mask. A spacer-forming material layer is formed over and conformal with the liner layer. The spacer-forming material layer is then etched to form a spacer mask and to expose a portion of the liner layer. The exposed portion of the liner layer and the template mask are then removed. Finally, in one embodiment, an image of the spacer mask is transferred to the stack of films.

What is claimed is:

1. A method of self-aligned dual patterning, comprising:
providing a substrate having a stack of films thereon;
forming a template mask above said stack of films;
forming a liner layer above said stack of films and conformal with said template mask;
forming a spacer-forming material layer over and conformal with said liner layer;
etching said spacer-forming material layer to form a spacer mask and to expose a portion of said liner layer;
removing said portion of said liner layer and said template mask; and
transferring an image of said spacer mask to said stack of films.

2. The method of claim 1, wherein said template mask and said liner layer have a similar etch characteristic.

3. The method of claim 2, wherein both said template mask and said liner layer comprise amorphous silicon.

4. The method of claim 1, wherein said spacer-forming material layer comprises a material selected from the group consisting of silicon oxide and silicon nitride.

5. The method of claim 1, wherein the contribution of the height of said liner layer is approximately in the range of 3-5% of the total height of the combined heights of said liner layer and the features of said template mask.

6. The method of claim 1, wherein said liner layer protects said stack of films during the etching of said spacer-forming material layer to form said spacer mask.

7. A method of self-aligned dual patterning, comprising:
providing a substrate having a stack of films thereon, wherein a first film of said stack of films is farthest from said substrate;
forming a template mask above said first film of said stack of films;
forming a liner layer above said first film of said stack of films and conformal with said template mask;
forming a spacer-forming material layer over and conformal with said liner layer, wherein said spacer-forming material layer and said first film of said stack of films have a similar etch characteristic;
etching said spacer-forming material layer to form a spacer mask and to expose a portion of said liner layer;
removing said portion of said liner layer and said template mask; and
transferring an image of said spacer mask to said stack of films.

8. The method of claim 7, wherein said spacer-forming material layer comprises a material selected from the group consisting of silicon oxide and silicon nitride, and wherein said first film of said stack of films comprises silicon oxy-nitride.

9. The method of claim 7, wherein said template mask and said liner layer have a similar etch characteristic.

10. The method of claim 9, wherein both said template mask and said liner layer comprise amorphous silicon.

11. The method of claim 7, wherein the contribution of the height of said liner layer is approximately in the range of 3-5% of the total height of the combined heights of said liner layer and the features of said template mask.

12. The method of claim 7, wherein said liner layer protects said first film of said stack of films during the etching of said spacer-forming material layer to form said spacer mask.

13. A method of self-aligned dual patterning, comprising:
providing a substrate having a stack of films thereon;
forming a template mask above said stack of films, wherein a line of said template mask has a first width;
forming a liner layer above said stack of films and conformal with said template mask;
forming a spacer-forming material layer over and conformal with said liner layer;
etching said spacer-forming material layer to form a spacer mask and to expose a portion of said liner layer, wherein a line of said spacer mask has a second width, and wherein said second width is approximately equal to the sum of said first width of said template mask and two times the thickness of said liner layer;
removing said portion of said liner layer and said template mask; and
transferring an image of said spacer mask to said stack of films.

14. The method of claim 13, wherein said template mask and said liner layer have a similar etch characteristic.

15. The method of claim 14, wherein both said template mask and said liner layer comprise amorphous silicon.

16. The method of claim 13, wherein said spacer-forming material layer and the top film of said stack of films have a similar etch characteristic.

17. The method of claim 16, wherein said spacer-forming material layer comprises a material selected from the group consisting of silicon oxide and silicon nitride, and wherein the top film of said stack of films comprises silicon oxy-nitride.

18. The method of claim 13, wherein the contribution of the height of said liner layer is approximately in the range of 3-5% of the total height of the combined heights of said liner layer and the features of said template mask.

19. The method of claim 18, wherein the thickness of said liner layer is approximately in the range of 5-10 nanometers.

20. The method of claim 13, wherein said liner layer protects said stack of films during the etching of said spacer-forming material layer to form said spacer mask.
